(19) United States
(12) Patent Application Publication
(10) Pub. No.: US 2025/0185372 A1
(43) Pub. Date: Jun. 5, 2025

(54) DISPLAY DEVICE

(71) Applicant: LG DISPLAY CO., LTD., Seoul (KR)

(72) Inventors: Jae Yong YUN, Paju-si (KR); Jae Kwang LEE, Paju-si (KR)

(73) Assignee: LG DISPLAY CO., LTD., Seoul (KR)

(21) Appl. No.: 18/945,172

(22) Filed: Nov. 12, 2024

(30) Foreign Application Priority Data
Nov. 30, 2023 (KR) 10-2023-0171070

(51) Int. Cl. H01L 27/12; H01L 25/16; H01L 33/62

(52) U.S. Cl. CPC H10D 86/60; H01L 25/167; H10D 86/441; H10H 20/857

(57) ABSTRACT

A display device may include a substrate, a display area, a non-display area, a bending area, a connection wire area, a pad part, and a first area included in the pad part. The first area may include: a first insulating layer disposed on the substrate; a first connection wire disposed on the first insulating layer; a second connection wire disposed on the first connection wire; a second insulating layer disposed on the second connection wire; a third connection wire disposed on the second insulating layer; and a fourth connection wire disposed on the third connection wire.

### CROSS-REFERENCE TO RELATED APPLICATION

This application claims the benefit of and priority to Korean Patent Application No. 10-2023-0171070, filed Nov. 30, 2023, the entire contents of which are incorporated herein by reference for all purpose.

### BACKGROUND

### 1. Technical Field

Embodiments of the present disclosure relate to a display device, and particularly to, for example, without limitation, a display device with an inorganic light-emitting diode as a light source.

### 2. Discussion of the Related Art

Electroluminescent display devices include an organic light-emitting display device in which an organic light-emitting diode (OLED) is disposed, and an inorganic light-emitting display device (hereinafter referred to as an “LED display device”) in which an inorganic light-emitting diode (hereinafter referred to as an “LED”) is disposed.

Since the electroluminescent display device displays an image using a spontaneous emission element, it does not require a separate light source, e.g., a backlight unit, so that it may be implemented in thin and various forms.

The organic light-emitting display device needs to be designed to prevent the permeation of oxygen and moisture since the permeation of moisture and oxygen may cause oxidation between an organic light-emitting layer and an electrode.

Recently, as an example of the inorganic light-emitting display device, a micro-LED display device in which micro-LEDs are disposed in pixels has been gaining attention as a next generation display device. The micro LEDs may be inorganic LEDs with a size of 100 μm or less. The micro LEDs may be fabricated through a separate semiconductor process and may be transferred to pixel positions on the display panel substrate of the display device to be disposed in each sub-pixel for each color.

The description of the related art should not be assumed to be prior art merely because it is mentioned in or associated with this section. The description of the related art includes information that describes one or more aspects of the subject technology, and the description in this section does not limit the invention.

### SUMMARY

One or more aspects of the present disclosure are directed to solving a defect in which the insulating layer and the connection wire may be damaged and disconnected due to the load applied when attaching a chip on film (COF) to a pad part and a first area with an adhesive, such as an anisotropic conductive film (ACF), containing a conductive ball, in a structure in which one connection wire is formed on one insulating layer. In addition, one or more aspects of the present disclosure are directed to reducing bonding resistance between a circuit component and a signal wire when attaching the COF to the pad part and the first area with the adhesive, such as ACF, containing a conductive ball, and to solve a defect in which cracks occur in an insulating layer.

The problem to be solved by one or more aspects of the present disclosure is not limited to the problem mentioned above, and other problems not mentioned herein will be clearly understood by those skilled in the art from the following description.

The above one or more aspects may be achieved by a display device which includes: a substrate, a display area, a non-display area, a bending area, a connection wire area, a pad part, and a first area included in the pad part, wherein the first area includes: a first insulating layer disposed on the substrate; a first connection wire disposed on the first insulating layer; a second connection wire disposed on the first connection wire; a second insulating layer disposed on the second connection wire; a third connection wire disposed on the second insulating layer; and a fourth connection wire disposed on the third connection wire.

In addition, the above one or more aspects may be achieved by a display device including a substrate. a display area, a non-display area, a bending area, a connection wire area, a pad part, and a first area included in the pad part, wherein the first area includes: a first insulating layer disposed on the substrate; a first connection wire disposed on the first insulating layer; a second insulating layer disposed on the first connection wire; a second connection wire disposed on the second insulating layer; a third connection wire disposed on the second connection wire; and a fourth connection wire disposed on the third connection wire.

According to one or more aspects of the present disclosure, in the first area included in the pad part, at least one of the second insulating layer, the third insulating layer, and the fourth insulating layer is removed by patterning, allowing at least two or more connection wires to overlap. Accordingly, when attaching a COF to the pad part and the first area with an adhesive, such as ACF, containing a conductive ball, in a structure in which one connection wire is formed on one insulating layer, a defect in which the insulating layer and the connection wire may be damaged and disconnected by the load may be prevented. In addition, according to the present disclosure, when attaching the COF to the pad part and the first area with an adhesive, such as ACF, containing a conductive ball, bonding resistance between a circuit component and a signal wire may be reduced, and a defect in which cracks occur in the insulating layer may be prevented.

The various advantages and beneficial effects of the present disclosure are not limited to the above description, and other effects not mentioned will be clearly understood by those skilled in the art from the following description.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a diagram illustrating a display device according to one embodiment of the present disclosure;

FIG. 2 is an enlarged view of area A of FIG. 1;

FIG. 3 is a diagram illustrating a partial area of a pixel;

FIG. 4 is a cross-sectional view taken along line I-I′ in FIG. 3;

FIG. 5 is a cross-sectional view taken along line II-II′ in FIG. 3;

FIG. 6 is a cross-sectional view taken along line III-III′ in FIG. 3;

FIG. 7 is a cross-sectional view illustrating an example in which a main light-emitting element and a sub-light-emitting element are electrically connected to a pixel driving circuit;

FIG. 8 is a diagram illustrating a display device according to another embodiment of the present disclosure;

FIG. 9 is a cross-sectional view taken along line IV-IV′ in FIG. 8;

FIG. 10A is a diagram illustrating a display device according to another embodiment of the present disclosure;

FIG. 10B is an enlarged view of area B of FIG. 10A;

FIG. 11 is a cross-sectional view taken along line A-A′ in FIG. 10B;

FIG. 12 is an enlarged view of area X of FIG. 10B;

FIG. 13A is a cross-sectional view of a pad part according to a first embodiment of the present disclosure taken along line B-B′ in FIG. 12;

FIG. 13B is a cross-sectional view of a pad part according to the first embodiment of the present disclosure taken along line C-C′ in FIG. 12;

FIG. 14A is a cross-sectional view of a pad part according to a second embodiment of the present disclosure taken along line B-B′ in FIG. 12;

FIG. 14B is a cross-sectional view of a pad part according to the second embodiment of the present disclosure taken along line C-C′ in FIG. 12;

FIG. 15A is a cross-sectional view of a pad part according to a third embodiment of the present disclosure taken along line B-B′ in FIG. 12;

FIG. 15B is a cross-sectional view of a pad part according to the third embodiment of the present disclosure taken along line C-C′ in FIG. 12;

FIG. 16A is a cross-sectional view of a pad part according to a fourth embodiment of the present disclosure taken along line B-B′ in FIG. 12; and

FIG. 16B is a cross-sectional view of a pad part according to the fourth embodiment of the present disclosure taken along line C-C′ in FIG. 12.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

The advantages and features of the present disclosure, and methods of achieving them will be apparent from the embodiments described in detail below in conjunction with the accompanying drawings. However, the present disclosure is not limited to the following embodiments, which may be implemented in various different forms; rather, the present embodiments are provided to make the disclosure of the present disclosure complete and to allow those skilled in the art to fully understand the scope of the present disclosure, and the present disclosure is defined only within the scope of the appended claims.

The shapes, sizes, proportions, angles, numbers and the like shown in the accompanying drawings for the purpose of describing the embodiments of the present disclosure are merely examples, and the present disclosure is not limited thereto. Like reference numerals generally denote like elements throughout the present disclosure. Further, in describing the present disclosure, detailed descriptions of known related technologies may be omitted so as not to unnecessarily obscure the subject matter of the present disclosure.

The terms such as “comprising,” “including,” “having,” and “comprising” used herein are generally intended to allow other components to be added unless the terms are used with the term “only.” References to the singular shall be construed to include the plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In interpreting components, they are construed to include a margin of error, even if it is not explicitly stated.

When describing a positional or interconnected relationship between two components, by using terms such as “on top of,” “above,” “below,” “next to,” “connect or couple with,” “crossing,” “intersecting,” etc., one or more other components may be interposed between them unless “immediately” or “directly” is used.

When describing a temporal contextual relationship is described, by using terms such as “after,” “following,” “next to,” or “before,” it may not be continuous on a time scale unless “immediately” or “directly” is used.

First, second, and the like may be used before the names of the components to distinguish the components, but the function or structure thereof is not limited by such ordinal number or component name. For ease of description, the ordinal numbers placed before the names of the same components may differ between embodiments.

The following embodiments may be combined or associated with each other in whole or in part, and various types of interlocking and driving are technically possible. The embodiments may be implemented independently of each other or together in an interrelated relationship.

Hereinafter, various embodiments of the present disclosure will be described in detail with reference to the accompanying drawings.

A display device according to one embodiment of the present disclosure includes a display panel having a display area or screen on which an image is displayed, and a pixel driving circuit that drives pixels of the display panel. The display area includes a pixel area in which the pixels are arranged. The pixel area includes a plurality of light-emitting areas. A light-emitting element is disposed in each of the light-emitting areas. The pixel driving circuit may be embedded in the display panel.

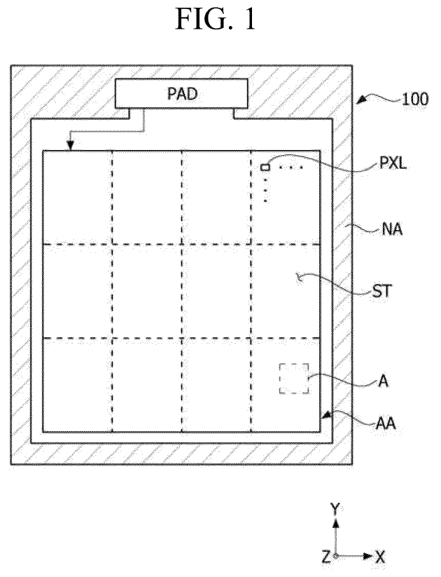

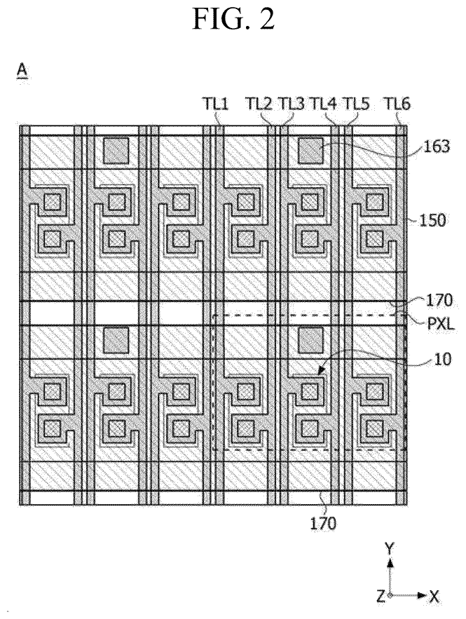

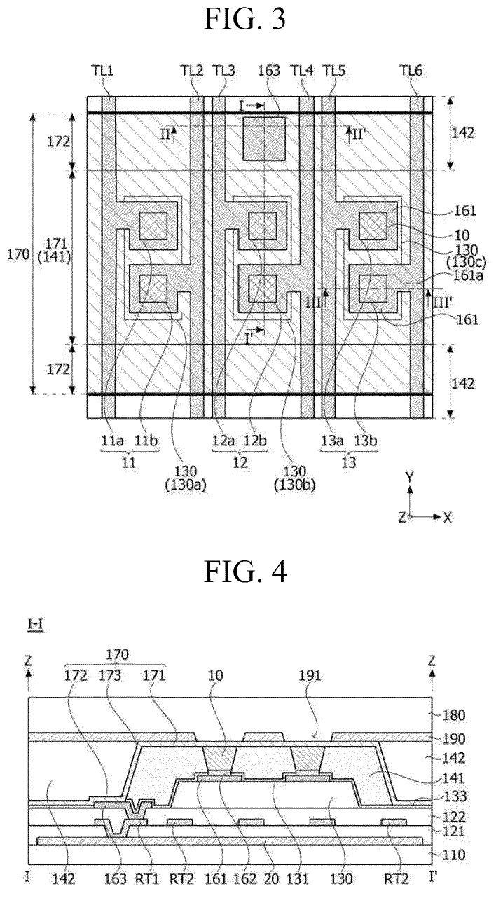

FIG. 1 is a diagram illustrating a display device according to one embodiment of the present disclosure. FIG. 2 is an enlarged view of an area A in FIG. 1. FIG. 3 is a diagram illustrating a partial area of a pixel.

Referring to FIGS. 1 and 2, a display device 100 according to an embodiment of the present disclosure includes a display panel on which an input image is visually reproduced. The display panel may include a display area AA in which the image is displayed and a non-display area NA in which no image is displayed. In the non-display area NA, various wires and driving circuits may be mounted and a pad area PAD may be disposed to which integrated circuits, printed circuits, etc. are connected. Here, the display panel may be a panel having a rectangular structure with a length in the X-axis direction, a width in the Y-axis direction, and a thickness in the Z-axis direction. The width and length of the display panel may be set to different design values depending on the area of application of the display device. The X-axis direction may mean width direction, row direction, or horizontal direction; the Y-axis direction may mean length direction, column direction, or vertical direction; and the Z-axis direction may mean up-down direction or thickness direction. In addition, the X-axis direction, Y-axis direction, and Z-axis direction may be perpendicular to each other, but they may also mean different directions that are not perpendicular to each other. Accordingly, each of the X-axis direction, Y-axis direction, and Z-axis direction may be described as one of a first direction, a second direction, and a third direction. In addition, the plane extending in the X-axis direction and the Y-axis direction may mean a horizontal plane.

A plurality of light-emitting elements 10 disposed in the display area AA to form a pixel PXL may be micro-sized inorganic light-emitting elements. The inorganic light-emitting elements may be grown on a silicon wafer and then attached to the display panel through a transfer process.

The transfer process of the light-emitting elements 10 may be performed for each pre-divided area. In FIG. 1, the display area AA is shown as being divided into twelve transfer regions ST, but the size or the number of divisions of the transfer regions is not limited thereto. The transfer process may be sequentially or simultaneously performed for first to twelfth transfer regions ST. A blue light-emitting element 10, a green light-emitting element 10, and a red light-emitting element 10 may be sequentially transferred to a transfer region ST.

In the non-display area NA, a data driving circuit or a gate driving circuit may be disposed and wires through which a control signal for controlling the driving circuits is supplied may be disposed. Here, the control signal may include various timing signals including a clock signal, an input data enable signal, and synchronization signals, and may be received through the pad area PAD.

The pixels PXL may be driven by the pixel driving circuit. The pixel driving circuit may receive a driving voltage, an image signal (digital signal), a synchronization signal synchronized with the image signal, and the like, and may output an anode voltage and a cathode voltage of the light-emitting element 10 to drive the plurality of pixels. The driving voltage may be a high potential voltage EVDD. The cathode voltage may be a low potential voltage EVSS commonly applied to the pixels. The anode voltage may be a voltage corresponding to a pixel data value of the image signal. The pixel driving circuit may be disposed in the non-display area NA, or may be disposed below the display area AA.

Each of the pixels PXL may include a plurality of sub-pixels having different colors. For example, the plurality of sub-pixels may include a red sub-pixel in which the light-emitting element 10 that emits light of a red wavelength is disposed, a green sub-pixel in which the light-emitting element 10 that emits light of a green wavelength is disposed, and a blue sub-pixel in which the light-emitting element 10 that emits light of a blue wavelength is disposed. The plurality of sub-pixels may further include a white sub-pixel.

Referring to FIGS. 2 and 3, the plurality of pixels PXL may be successively arranged in the first direction (the X-axis direction) and the second direction (the Y-axis direction). A plurality of sub-pixels of the same color may be disposed within a pixel of the display area AA. For example, each of the plurality of pixels may include a first red sub-pixel in which a first-first light-emitting element 11a that emits light of a red wavelength is disposed, a second red sub-pixel in which a first-second light-emitting element 11b that emits light of a red wavelength is disposed, a first green sub-pixel in which a second-first light-emitting element 12a that emits light of a green wavelength is disposed, a second green sub-pixel in which a second-second light-emitting element 12b that emits light of a green wavelength is disposed, a first blue sub-pixel in which a third-first light-emitting element 13a that emits light of a blue wavelength is disposed, and a second blue sub-pixel in which a third-second light-emitting element 13b that emits light of a blue wavelength is disposed. The first-first light-emitting element 11a, the second-first light-emitting element 12a, and the third-first light-emitting element 13a may be regarded as main light-emitting elements. The first-second light-emitting element 11b, the second-second light-emitting element 12b, and the third-second light-emitting element 13b may be regarded as sub-light-emitting elements.

One sub-pixel may include at least one or more light-emitting elements, and in the event that one light-emitting element becomes defective, the luminance of another light-emitting element may be increased to adjust the luminance of the sub-pixel. However, the embodiment is not necessarily limited thereto, and one sub-pixel may include only one light-emitting element.

A plurality of first electrodes 161 may each be disposed below the light-emitting element 10, and may be selectively connected to a plurality of signal wires TL1 to TL6 by an extension portion 161a. The high potential voltage may be applied to the pixel driving circuit through the signal wires TL1 to TL6. The signal wires TL1 to TL6 and the first electrodes 161 may be formed as integrated electrode patterns during the electrode patterning process.

For example, a first signal wire TL1 may be connected to an anode electrode of the first red sub-pixel, and a second signal wire TL2 may be connected to an anode electrode of the second red sub-pixel. A third signal wire TL3 may be connected to an anode electrode of the first green sub-pixel, and a fourth signal wire TL4 may be connected to an anode electrode of the second green sub-pixel. A fifth signal wire TL5 may be connected to an anode electrode of the first blue sub-pixel, and a sixth signal wire TL6 may be connected to an anode electrode of the second blue sub-pixel. In a case where one sub-pixel includes only one light-emitting element, the number of the signal wires TL may be reduced by half.

A second electrode 170 may be a cathode electrode that is disposed one for each row and applies a cathode voltage to the light-emitting elements 10 arranged successively in the first direction (the X-axis direction). A plurality of second electrodes 170 may be spaced apart from each other in the second direction (the Y-axis direction). The plurality of second electrodes 170 may be connected to the cathode voltage through a contact electrode 163. Each of the plurality of second electrodes 170 may be electrically connected to the contact electrode 163. However, the present disclosure is not necessarily limited thereto, and the second electrode 170 may be configured as one electrode layer without being divided into a plurality of electrodes and may function as a common electrode.

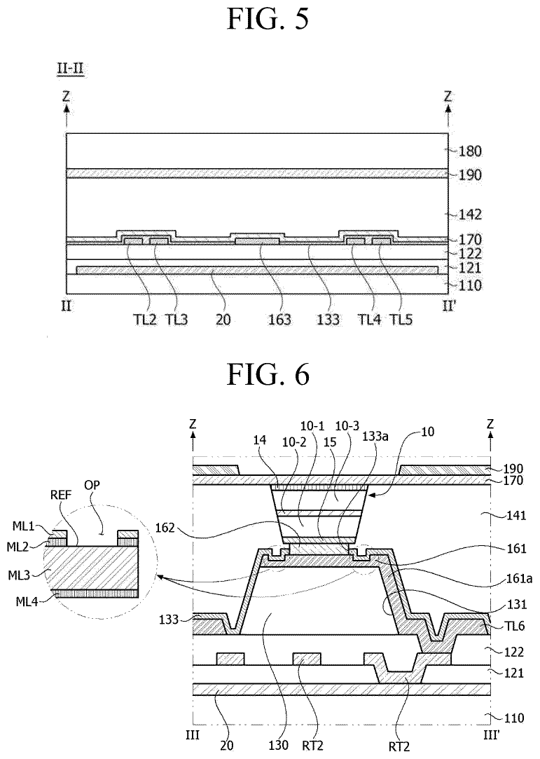

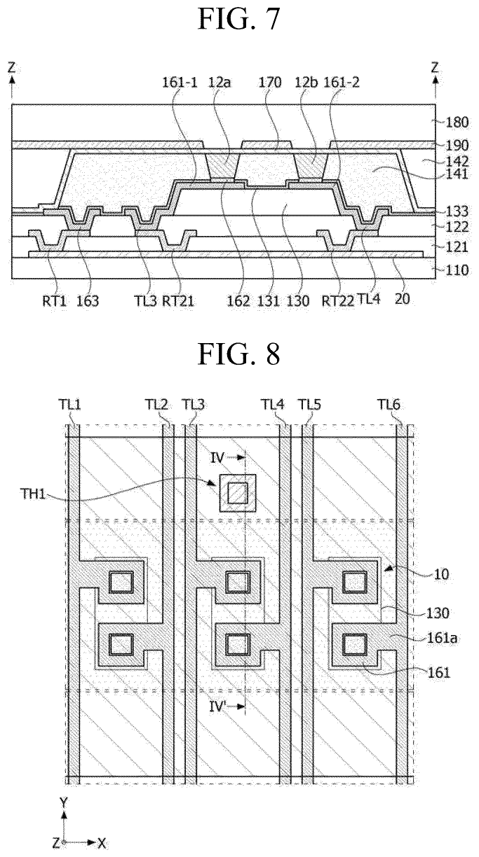

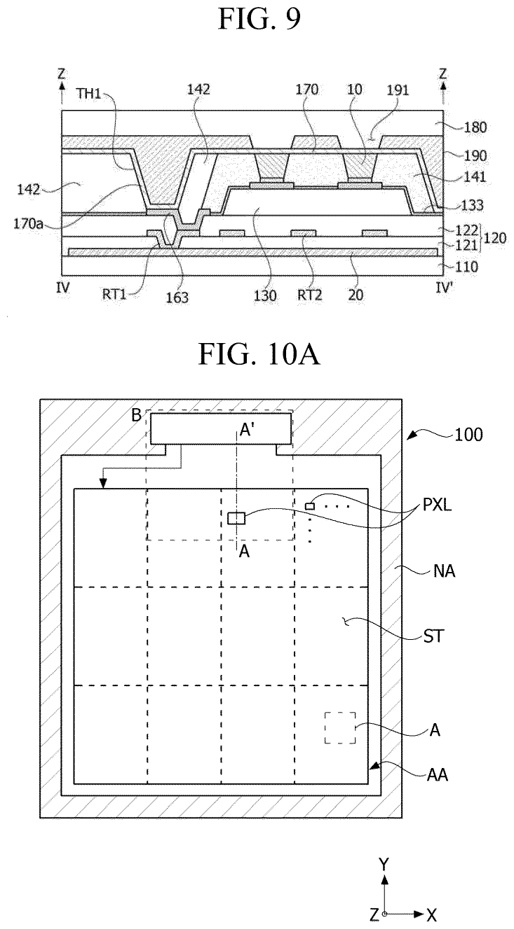

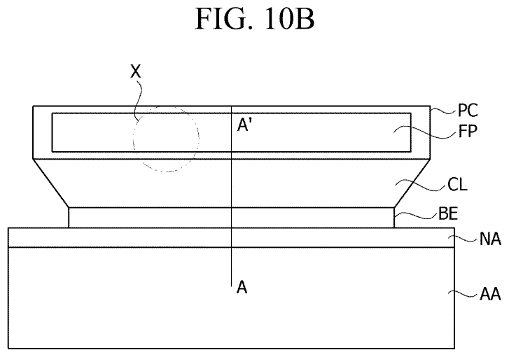

FIG. 4 is a cross-sectional view taken along line I-I′ in FIG. 3. FIG. 5 is a cross-sectional view taken along line II-II′ in FIG. 3. FIG. 6 is a cross-sectional view taken along line III-III′ in FIG. 3. FIG. 7 is a cross-sectional view illustrating an example in which two light-emitting elements are electrically connected to a pixel driving circuit.

Referring to FIGS. 3 to 5, the display device according to an embodiment includes the plurality of first electrodes 161 and the contact electrode 163 disposed above a substrate 110, the plurality of light-emitting elements 10 disposed above the plurality of first electrodes 161, a first optical layer 141 disposed between the plurality of light-emitting elements 10, and the second electrode 170 disposed on the plurality of light-emitting elements 10.

The substrate 110 may be made of plastic having flexibility. For example, the substrate 110 may be manufactured as a single-layer or multilayer substrate made of a material selected from polyimide, polyethylene terephthalate, polyethylene naphthalate, polycarbonate, polyethersulfone, polyarylate, polysulfone, and cyclic olefin copolymer, but is not limited thereto. For example, the substrate 110 may be a ceramic substrate or a glass substrate.

A pixel driving circuit 20 may be disposed in the display area AA on the substrate 110. The pixel driving circuit 20 may include a plurality of thin film transistors that use an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. When the pixel driving circuit 20 includes the plurality of thin film transistors, it may be formed on the substrate 110 by a thin film transistor (TFT) manufacturing process. In an embodiment, the pixel driving circuit 20 may be a collective term for the plurality of thin film transistors electrically connected to the light-emitting element 10.

The pixel driving circuit 20 may be a driving driver manufactured using a metal-oxide-semiconductor field effect transistor (MOSFET) manufacturing process on a single crystal semiconductor substrate 110. The driving driver may include the plurality of pixel driving circuits to drive the plurality of sub-pixels. When the pixel driving circuit 20 is implemented as the driving driver, an adhesive layer may be disposed on the substrate 110, and then the driving driver may be mounted on the adhesive layer by a transfer process.

A buffer layer 121 that covers the pixel driving circuit 20 may be disposed on the substrate 110. The buffer layer 121 may be made of an organic insulating material, e.g., a photosensitive photoacryl or photosensitive polyimide, but is not limited thereto.

The buffer layer 121 may be formed by stacking an inorganic insulating material, e.g., silicon nitride (SiNₓ) or silicon oxide (SiO₂), in multiple layers, or by stacking an organic insulating material and an inorganic insulating material in multiple layers.

An insulating layer 122 may be disposed on the buffer layer 121. The insulating layer 122 may be made of an organic insulating material, e.g., photosensitive photo acryl or photosensitive polyimide, but is not limited thereto. A connection wire may be disposed on the buffer layer 121. The connection wire may include a plurality of connection wires such as a first connection wire RT1 and a second connection wire RT2. The connection wire may be connected to its corresponding signal wire TL. The signal wire may include the first signal wire TL1 to the sixth signal wire TL6, but is not limited thereto. The connection wire may include a plurality of wire patterns disposed in different layers with one or more insulating layers interposed therebetween. The wire patterns disposed in different layers may be electrically connected through a contact hole penetrating the insulating layer.

A plurality of bank patterns 130 may be disposed on the insulating layer 122. At least one light-emitting element 10 may be disposed above each bank pattern 130. For example, a first light-emitting element 11 may be disposed above a first bank pattern 130a, a second light-emitting element 12 may be disposed above a second bank pattern 130b, and a third light-emitting element 13 may be disposed above a third bank pattern 130c.

The bank pattern 130 may be made of an organic insulating material, e.g., photosensitive photoacryl or photosensitive polyimide, but is not limited thereto. The bank pattern 130 may guide a position to which the light-emitting element 10 is to be attached during the transfer process of the light-emitting element 10. The bank pattern 130 may be omitted.

A solder pattern 162 may be disposed on the first electrode 161. The solder pattern 162 may be made of indium (In), tin (Sn), or an alloy thereof, but is not limited thereto.

The plurality of light-emitting elements 10 may each be mounted on the solder pattern 162. One pixel may include three colors of light-emitting elements 10. The first light-emitting element 11 may be a red light-emitting element, the second light-emitting element 12 may be a green light-emitting element, and the third light-emitting element 13 may be a blue light-emitting element. Two light-emitting elements may be mounted in each sub-pixel.

The first optical layer 141 may cover the plurality of light-emitting elements 10 and the bank pattern 130. Thus, the first optical layer 141 may cover between the plurality of light-emitting elements 10 and between the plurality of bank patterns 130. The first optical layer 141 may extend in the first direction (the X-axis direction) and be separated in the second direction (the Y-axis direction) to separate the pixels arranged to be spaced apart in the second direction. Accordingly, the first optical layer 141 may be separated between the pixel rows. Here, the row may refer to the first direction. In addition, a single pixel row formed of a plurality of pixels arranged along the first direction may be referred to as a pixel group. Accordingly, the display panel may include a plurality of pixel groups arranged to be spaced apart from each other in the second direction. For example, since the first optical layer 141 disposed along the first direction is positioned around the pixels, and the plurality of first optical layers 141 disposed to correspond to the plurality of pixel groups are positioned to be spaced apart from each other in the second direction, one first optical layer 141 positioned around the pixels forming a single row may be separated from another first optical layer 141 positioned around the pixels forming another row.

The first optical layer 141 may contain an organic insulating material in which fine metal particles such as titanium dioxide particles are dispersed. Light emitted from the plurality of light-emitting elements 10 may be scattered by the fine metal particles dispersed in the first optical layer 141 and emitted to the outside.

The second electrode 170 may be disposed on the plurality of light-emitting elements 10. The second electrode 170 may be connected in common to the plurality of pixels PXL. The second electrode 170 may be a thin electrode through which light is transmitted. The second electrode 170 may be made of a transparent electrode material, e.g., indium tin oxide (ITO), but is not necessarily limited thereto.

The second electrode 170 may extend in the first direction (the X-axis direction) and be separated in the second direction (the Y-axis direction). For example, a single second electrode 170 may be formed to extend in the first direction, and a plurality of second electrodes 170 extending in the first direction may be disposed to be spaced apart from each other in the second direction. In this case, the second electrode 170 may be disposed to correspond to each of the pixels that are spaced apart from each other in the second direction. The second electrode 170 may include a first region 171 disposed on the top surface of the light-emitting element 10 and the top surface of the first optical layer 141, a second region 172 in contact with the contact electrode 163 and electrically connected to the contact electrode 163, and a third region 173 disposed on the side surface of the first optical layer 141 and connecting the first region 171 to the second region 172.

In plan view, the plurality of second electrodes 170 may each overlap the first optical layer 141, and the third region 173 may cover the outer side surface of the first optical layer 141.

A second optical layer 142 may be an organic insulating material surrounding the periphery of the first optical layer 141. The second optical layer 142 may be disposed above the insulating layer 122 together with the first optical layer 141. The first optical layer 141 and the second optical layer 142 may contain the same material (e.g., siloxane). For example, the first optical layer 141 may be a siloxane containing titanium oxide (TiOₓ), and the second optical layer 142 may be a siloxane not containing titanium oxide (TiOₓ). However, the present disclosure is not necessarily limited thereto, and the first optical layer 141 and the second optical layer 142 may be formed of the same material or different materials.

According to an embodiment, the second region 172 of the second electrode 170 is connected to the contact electrode 163 in a state of being formed flat as a whole, so that excessive stress is not concentrated at a connection point to the contact electrode 163. Therefore, the occurrence of cracks in the second electrode 170 may be effectively prevented.

The second optical layer 142 may cover the second region 172 and the third region 173 of the second electrode 170. The top surface of the second optical layer 142 and the top surface of the first region 171 of the second electrode 170 may be coplanar. That is, the first region 171 and the second optical layer 142 may function as a planarization layer. As a result, since there is no level difference on the surface on which a black matrix 190 is formed, the pattern of the black matrix 190 may be easily formed on the first optical layer 141 and the second optical layer 142. However, the present disclosure is not limited thereto, and the top surfaces of the second optical layer 142 and the second electrode 170 may have different heights.

The black matrix 190 may be an organic insulating material to which a black pigment is added. The second electrode 170 may be in contact with the contact electrode 163 below the black matrix 190. A transmission hole 191 through which light from the light-emitting element 10 is emitted to the outside may be formed between the patterns of the black matrix 190. The transmission hole 191 may overlap the light-emitting element 10 in the Z-axis direction, and a partial area of the black matrix 190 may overlap the first optical layer 141 in the Z-axis direction. Here, the Z-axis direction may be referred to as the third direction. Accordingly, the black matrix 190 may overcome a problem that light emitted from the adjacent light-emitting elements 10 is mixed by the first optical layer 141 and then emitted.

A cover layer 180 may be an organic insulating material that covers the black matrix 190 and the second electrode 170. In FIGS. 2 and 3, the configurations of the black matrix 190 and the cover layer 180 are omitted.

The contact electrode 163 may be electrically connected to the first connection wire RT1 disposed therebelow, and the first connection wire RT1 may be connected to the pixel driving circuit 20. Thus, a cathode voltage may be applied to the second electrode 170 through the contact electrode 163. The first electrode 161 may be electrically connected to the second connection wire RT2. This will be described later.

Referring to FIG. 5, the contact electrode 163 and the signal wires TL1 to TL6 may be disposed on the same plane. The pixel driving circuit 20 may be disposed below the contact electrode 163 and the signal wires TL1 to TL6. When the pixel driving circuit 20 is a driving driver, a plurality of driving drivers may be disposed in the display panel.

A passivation layer 133 may expose the contact electrode 163 such that the contact electrode 163 and the second electrode 170 are electrically connected to each other. Further, the passivation layer 133 may insulate the signal wires TL2 to TL5 from the second electrode 170. Here, the passivation layer 133 may be made of an inorganic material.

Referring to FIG. 6, a connection portion 161a of the first electrode 161 may extend to one side surface 131 of the bank pattern 130 to be electrically connected to the second connection wire RT2 disposed on the buffer layer 121.

The first electrode 161, the connection portion 161a, the signal wire TL, and/or the connection wires RT1 and RT2 may include a single-layer or multilayer metal layer selected from titanium (Ti), molybdenum (Mo), and aluminum (Al).

The first electrode 161 or the signal wire TL may be formed to have a metal stack structure in which a plurality of metal layers are formed using metals of different materials, thicknesses, and the like. In this case, the first electrode 161, the connection portion 161a, and the signal wire TL may be simultaneously formed through the same manufacturing process. Here, the thickness may represent a width between one surface and the other surface of the metal layer disposed in the Z-axis direction.

The first electrode 161 may include a first metal layer ML1 disposed below the solder pattern 162, a second metal layer ML2 disposed below the first metal layer ML1, a third metal layer ML3 disposed below the second metal layer ML2, and a fourth metal layer ML4 disposed below the third metal layer ML3. When the first electrode 161 is formed of the first metal layer ML1, the second metal layer ML2, the third metal layer ML3, and the fourth metal layer ML4, the first electrode 161 may be deposited in the order of the fourth metal layer MLA, the third metal layer ML3, the second metal layer ML2, and the first metal layer ML1, and then patterned by performing a photolithography process and an etching process.

The first metal layer ML1 may be disposed to be in contact with the lower portion of the solder pattern 162 and may be electrically connected to the solder pattern 162.

In addition, the first metal layer ML1 may include a transparent conductive oxide layer such as indium tin oxide (ITO) or indium zinc oxide (IZO) having good adhesion and corrosion resistivity and acid resistivity. Here, the first metal layer ML1 may be referred to as an adhesive layer.

The second metal layer ML2 may be formed of a material having a different resistance value than each of the first metal layer ML1 and the third metal layer ML3. In this case, the second metal layer ML2 may be formed of a material that has a lower light reflectivity but a higher resistance value than the third metal layer ML3. For example, the second metal layer ML2 may contain titanium (Ti) or molybdenum (Mo).

The third metal layer ML3 may be formed of a material having a higher light reflectivity than the first metal layer ML1. In this case, the third metal layer ML3 may be formed of a material having a higher light reflectivity than the second metal layer ML2. For example, the third metal layer ML3 may contain aluminum (Al) or silver (Ag).

That is, the light reflectivity of the third metal layer ML3 may be greater than the light reflectivity of each of the first metal layer ML1 and the second metal layer ML2.

The fourth metal layer ML4 may be formed of the same material as the second metal layer ML2. For example, the fourth metal layer ML4 may contain titanium (Ti) or molybdenum (Mo).

After forming up to the first metal layer ML1, a reflective aperture OP may be formed in the first electrode 161. The reflective aperture OP may be a region in which the first metal layer ML1 and the second metal layer ML2 are removed to expose only a portion of the third metal layer ML3. The reflective aperture OP may have a shape surrounding the solder pattern 162 in plan view, and may be circular or quadrangular, but is not limited thereto.

Light emitted from the light-emitting element 10 may be reflected from the surface REF of the third metal layer ML3 exposed through the reflective aperture OP, resulting in an increase in the light efficiency of the display device.

The passivation layer 133 may be disposed on the first electrode 161 and the signal wire TL and may include an aperture hole 133a that exposes the solder pattern 162. Here, the aperture hole 133a exposing the solder pattern 162 may be referred to as a first aperture hole. In this case, the reflective aperture OP may be formed to surround the first aperture hole.

The light-emitting element 10 may include a first conductivity type semiconductor layer 10-1, an active layer 10-2 disposed on the first conductivity type semiconductor layer 10-1, and a second conductivity type semiconductor layer 10-3 disposed on the active layer 10-2. A first driving electrode 15 may be disposed below the first conductivity type semiconductor layer 10-1 and a second driving electrode 14 may be disposed on the second conductivity type semiconductor layer 10-3.

The light-emitting element 10 may be formed on a silicon wafer by using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first conductivity type semiconductor layer 10-1 may be implemented with a compound semiconductor such as a group III-V or a group II-VI and may be doped with a first dopant. The first conductivity type semiconductor layer 10-1 may be formed of one or more of semiconductor materials having a composition formula of Alₓ₁In_{y1}Ga_{(1-x1-y1)}N (0≤x1≤1, 0≤y1≤1, 0≤x1+y1≤1), InAlGaN, AlGaAs, GaP, GaAs, GaInP, and AlGaInP, but is not limited thereto. When the first dopant is an n-type dopant such as Si, Ge, Sn, Se, or Te, the first conductivity type semiconductor layer 10-1 may be an n-type nitride semiconductor layer. However, when the first dopant is a p-type dopant, the first conductivity type semiconductor layer 10-1 may be a p-type nitride semiconductor layer.

The active layer 10-2 is a layer in which electrons (or holes) injected through the first conductivity type semiconductor layer 10-1 and holes (or electrons) injected through the second conductivity type semiconductor layer 10-3 meet. The active layer 10-2 may transition to a low energy level as the electrons and the holes recombine, and may generate light having a wavelength corresponding thereto.

The active layer 10-2 may have any one structure selected from a single well structure, a multi-well structure, a single quantum well structure, a multi-quantum well (MQW) structure, a quantum dot structure, and a quantum wire structure, but the structure of the active layer 10-2 is not limited thereto. The active layer 10-2 may generate light in a visible wavelength band. For example, the active layer 10-2 may output light in any one of blue, green, and red wavelength bands.

The second conductivity type semiconductor layer 10-3 may be disposed on the active layer 10-2. The second conductivity type semiconductor layer 10-3 may be implemented with a compound semiconductor such as a group III-V or a group II-VI, and may be doped with a second dopant. The second conductivity type semiconductor layer 10-3 may be formed of a semiconductor material having a composition formula of Inₓ₂Al_{y2}Ga_{1-x2-y2}N (0≤x≤1, 0≤y2≤1, 0≤x2+y2≤1), or a material selected from AlInN, AlGaAs, GaP, GaAs, GaAsP, AlGaInP, and AlGaInP. When the second dopant is a p-type dopant such as Mg, Zn, Ca, Sr, or Ba, the second conductivity type semiconductor layer 10-3 doped with the second dopant may be a p-type nitride semiconductor layer. When the second dopant is an n-type dopant, the second conductivity type semiconductor layer 10-3 may be an n-type nitride semiconductor layer.

In an embodiment, a vertical structure has been described in which the driving electrodes 14 and 15 are disposed on the top and bottom of the light-emitting structure. However, the light-emitting element may have a lateral structure or a flip chip structure other than the vertical structure.

Referring to FIG. 7, a main light-emitting element 12a and a sub-light-emitting element 12b of the sub-pixel may be disposed on the bank pattern 130. The second light-emitting element 12 is exemplarily described. A first-first electrode 161-1 connected to the main light-emitting element 12a may extend to one side surface of the bank pattern 130 to be electrically connected to a second-first connection wire RT21 disposed therebelow. A first-second electrode 161-2 connected to the sub-light-emitting element 12b may extend to the other side surface of the bank pattern 130 to be electrically connected to a second-second connection wire RT22 disposed therebelow.

The pixel driving circuit 20 may apply an anode voltage to the main light-emitting element 12a by means of the second-first connection wire RT21, and may apply an anode voltage to the sub-light-emitting element 12b by means of the second-second connection wire RT22. The pixel driving circuit 20 may apply a cathode voltage to the main light-emitting element 12a and the sub-light-emitting element 12b through the first connection wire RT1 and the second electrode 170.

The pixel driving circuit 20 may adjust the luminance by driving only the main light-emitting element 12a, or may adjust the luminance by simultaneously driving the main light-emitting element 12a and the sub-light-emitting element 12b. In a case where the main light-emitting element 12a is turned into a dark point, the luminance may be adjusted by driving only the sub-light-emitting element 12b.

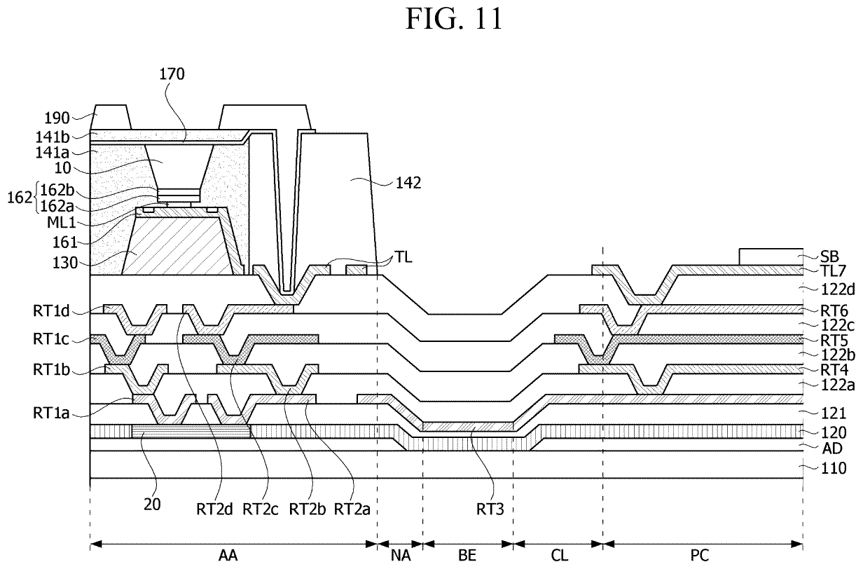

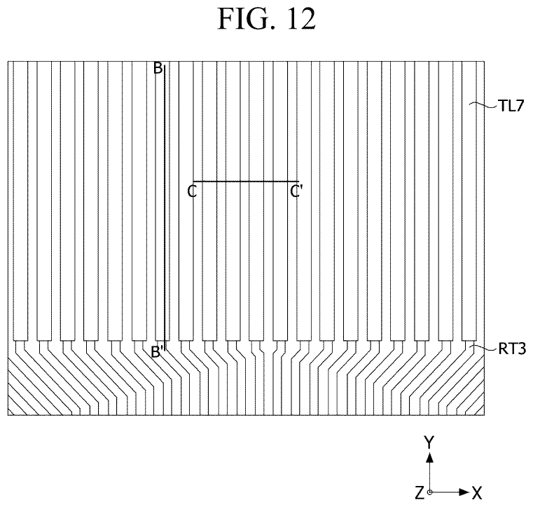

FIG. 8 is a diagram illustrating a display device according to another embodiment of the present disclosure. FIG. 9 is a cross-sectional view taken along line IV-IV′ in FIG. 8.

Referring to FIGS. 8 and 9, the second electrode 170 may be electrically connected to the contact electrode 163 through a contact hole TH1 formed in the second optical layer 142. The second optical layer 142 may include the contact hole TH1 exposing the contact electrode 163. The second electrode 170 inserted into the contact hole TH1 of the second optical layer 142 may be in contact with the top surface of the contact electrode 163. The contact hole TH1 may be formed in an outer region of the pixel.

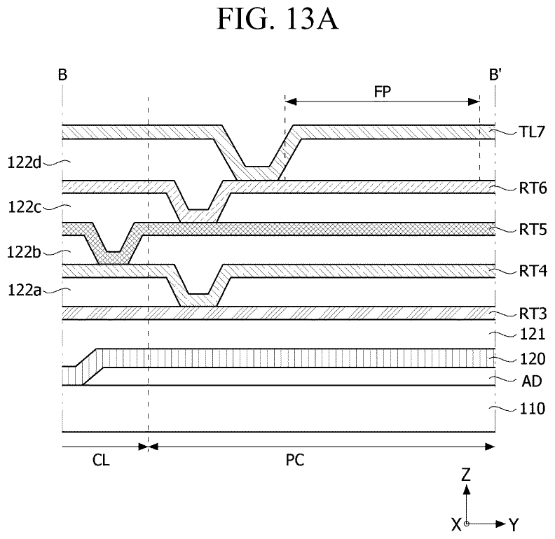

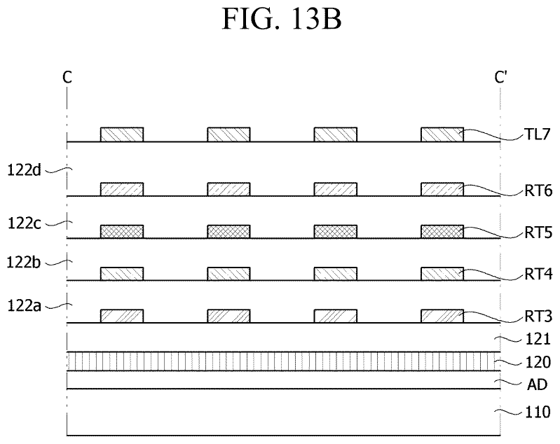

FIG. 10A is a diagram illustrating a display device according to another embodiment of the present disclosure. FIG. 10B is an enlarged view of area B of FIG. 10A. FIG. 11 is a cross-sectional view taken along line A-A′ in FIG. 10B.

In the following description, details regarding configurations similar to those included in the embodiments described in FIGS. 1 to 9 are omitted to avoid redundancy, and the focus is placed on other features.

Referring to FIGS. 10A and 10B, the display panel may include the display area AA in which an image is displayed and the non-display area NA in which an image is not displayed. In the non-display area NA, various wires and driving circuits may be mounted, and a pad part PC to which an integrated circuit, a printed circuit, and the like are connected may be disposed. A bending area BE may be disposed between the non-display area NA and the pad part PC, and a connection wire area CL may be disposed between the bending area BE and the pad part PC.

In the non-display area NA, the data driving circuit or the gate driving circuit may be disposed, and wires through which control signals for controlling the driving circuits are supplied may be disposed. Here, the control signals may include various timing signals, including a clock signal, an input data enable signal, and synchronization signals, and may be received from the pad part PC through wires disposed in the connection wire area CL.

The pad part PC may include a first area (film on panel) FP to which a chip on film (COF) is attached. As will be described later, some insulating layers may be removed from the first area FP.

A circuit component SB may be directly disposed on the pad part PC or may be attached to the pad part PC in the form of a COP or COF.

The circuit component SB may include a printed circuit board (PCB). The chip on film (COF) may process various signals inputted from the printed circuit board (PCB) and output them toward the display panel. To this end, one end of the chip on film (COF) may be attached to the display panel and the other end opposite to the one end may be attached to the printed circuit board (PCB).

Various driving circuits such as a timing controller may be mounted on the printed circuit board (PCB), and various signals generated by the driving circuits may be outputted toward the chip-on film (COF). The printed circuit board (PCB) may include, for example, a flexible printed circuit board (FPCB).

The display panel and the chip-on-film (COF) overlapping at least a portion thereof may be bonded by an anisotropic conductive film (ACF) interposed therebetween.

Referring to FIG. 11, the display device according to another embodiment of the present disclosure includes the plurality of first electrodes 161 disposed above the substrate 110, the plurality of light-emitting elements 10 disposed above the plurality of first electrodes 161, the first optical layer 141 disposed between the plurality of light-emitting elements 10, and the second electrode 170 disposed on the plurality of light-emitting elements 10.

An adhesive layer AD may be disposed on the substrate 110. There may be a region in the non-display area NA or the bending area BE from which the adhesive layer AD is removed. This is because there is a risk that the organic layer may be damaged or broken in the bending area BE as there are more organic layers in the bending area BE. The adhesive layer AD may be selected from, for example, an adhesive polymer, an epoxy resist, a UV resin, a polyimide-based material, an acrylate-based material, a urethane-based material, and polydimethylsiloxane (PDMS), but is not limited thereto.

The pixel driving circuit 20 implemented as a driving driver may be disposed on the adhesive layer AD in the display area AA.

A protective layer 120 for protecting the pixel driving circuit 20 may be formed on the adhesive layer AD. The protective layer 120 may cover at least a portion or all of the side surface of the pixel driving circuit 20, and may cover a portion of the top surface of the pixel driving circuit 20. The protective layer 120 may cover the entire substrate 110, and may cover a portion or all of the pad part PC. The protective layer 120 may be made of an organic insulating material, e.g., photosensitive photoacryl or photosensitive polyimide, but is not limited thereto.

The buffer layer 121 covering the pixel driving circuit 20 may be disposed on the protective layer 120. When the protective layer 120 covers only a portion of the pad part PC, the side surface of the protective layer 120 may be covered by the buffer layer 121.

The insulating layer 122 may be disposed on the buffer layer 121. A first-a connection wire RT1a, a second-a connection wire RT2a, and a third connection wire RT3 may be disposed in the same process on the buffer layer 121.

A first insulating layer 122a covering the first-a connection wire RT1a, the second-a connection wire RT2a, and the third connection wire RT3 may be disposed on the buffer layer 121.

A first-b connection wire RT1b, a second-b connection wire RT2b, and a fourth connection wire RT4 may be disposed in the same process on the first insulating layer 122a.

A second insulating layer 122b covering the first-b connection wire RT1b, the second-b connection wire RT2b, and the fourth connection wire RT4 may be disposed on the first insulating layer 122a.

A first-c connection wire RT1c, a second-c connection wire RT2c, and a fifth connection wire RT5 may be disposed in the same process on the second insulating layer 122b.

A third insulating layer 122c covering the first-c connection wire RT1c, the second-c connection wire RT2c, and the fifth connection wire RT5 may be disposed on the second insulating layer 122b.

A first-d connection wire RT1d, a second-d connection wire RT2d, and a sixth connection wire RT6 may be disposed in the same process on the third insulating layer 122c.

A fourth insulating layer 122d covering the first-d connection wire RT1d, the second-d connection wire RT2d, and the sixth connection wire RT6 may be disposed on the third insulating layer 122c. The fourth insulating layer 122d covers the substrate 110 in FIG. 11, but this is merely an example. As the number of insulating layers in the bending area BE increases, a defect in which the insulating layer is damaged during bending may occur. Although not shown in the drawings, the fourth insulating layer 122d may not be disposed in the bending area BE, and the non-display area NA and the connection wire area CL are adjacent to the bending area BE. The bending area BE may have n (where 0<n<5 and n is an integer) insulating layers disposed therein. The third connection wire RT3 may extend from the pad part PC to the display area AA, and only the third connection wire RT3 and n insulating layers may be disposed in the bending area BE.

The plurality of signal wires TL, the contact electrode 163, and a seventh signal wire (or connection wire) TL7 may be disposed in the same process on the fourth insulating layer 122d. That is, the plurality of signal wires TL, the contact electrode 163, and the seventh signal wire TL7 may be disposed on the same layer. The seventh signal wire TL7 may further have an ITO layer formed on a metal layer. Therefore, the seventh signal wire TL7 may have more metal layers or may have one more meal layer compared to the other signal wires.

The term “things disposed on the same layer” may mean “they are formed entirely on any one layer and then separated by a patterning process or the like.” However, it is not necessarily limited thereto, and as long as a plurality of wires or electrodes are formed on the same layer even though they are different in height, the plurality of wires or electrodes may be defined as being disposed on the same layer.

The first-a connection wire RT1a, the first-b connection wire RT1b, the first-c connection wire RT1c, the first-d connection wire RT1d, and the plurality of signal wires TL may be electrically connected through contact holes penetrating the insulating layer on which they are respectively disposed.

The second-a connection wire RT2a, the second-b connection wire RT2b, the second-c connection wire RT2c, the second-d connection wire RT2d, and the contact electrode 163 may be electrically connected through contact holes penetrating the insulating layer on which they are respectively disposed.

The anode voltage supplied by the pixel driving circuit 20 may be supplied to the light-emitting element 10 through the first-a connection wire RT1a, the first-b connection wire RT1b, the first-c connection wire RT1c, the first-d connection wire RT1d, the plurality of signal wires TL, and the first electrode 161.

The cathode voltage supplied by the pixel driving circuit 20 may be supplied to the light-emitting element 10 through the second-a connection wire RT2a, the second-b connection wire RT2b, the second-c connection wire RT2c, the second-d connection wire RT2d, the plurality of signal wires TL, and the first electrode 161.

The connection wires listed above are examples, and the connection wires may include a plurality of wire patterns disposed in different layers with one or more insulating layers interposed therebetween. The wire patterns disposed in different layers may be electrically connected through contact holes penetrating the insulating layer.

The third connection wire RT3 is disposed on the buffer layer 121. The third connection wire RT3 may extend from the display area AA to the pad part PC.

The fourth connection wire RT4 may be disposed on the first insulating layer 122a and may extend to the pad part PC and the connection wire area CL.

The fifth connection wire RT5 may be disposed on the second insulating layer 122b and may extend to the pad part PC and the connection wire area CL.

The sixth connection wire RT6 may be disposed on the third insulating layer 122c and may extend to the pad part PC and the connection wire area CL.

The seventh signal wire TL7 may be disposed on the fourth insulating layer 122d and may extend to the pad part PC and the connection wire area CL. Within the pad part PC, portions of the fourth connection wire RT4, the fifth connection wire RT5, the sixth connection wire RT6, and the seventh signal wire TL7 may extend out of the first area FP. The first insulating layer 122a, the second insulating 122b, the third insulating layer 122c, and the fourth insulating layer 122d may be disposed in an area other than the first area FC within the pad part PC.

Signals from the circuit component SB, such as a printed circuit board (PCB), may be transmitted to the pixel driving circuit 20 disposed in the display area AA through the chip-on-film (COF), the seventh signal wire TL7, the sixth connection wire RT6, the fifth connection wire RT5, the fourth connection wire RT4, and the third connection wire RT3.

The plurality of bank patterns 130 may be disposed on the insulating layer 122. At least one light-emitting element 10 may be disposed on each bank pattern 130. For example, referring to FIG. 3, the first light-emitting element 11 may be disposed on the first bank pattern 130a, the second light-emitting element 12 may be disposed on the second bank pattern 130b, and the third light-emitting element 13 may be disposed on the third bank pattern 130c.

The first electrode 161 may be disposed on the bank pattern 130. In the present embodiment, the first electrode 161 may include the plurality of metal layers ML2, ML3, and ML4 excluding the first metal layer ML1 during its formation, and in a separate process, the first metal layer ML1 may be disposed only in a region overlapping the first electrode 161 and the light-emitting element 10. The aperture OP may be disposed in the first electrode 161. In the present embodiment, the aperture OP may be formed by removing the second metal layer ML2. The first metal layer ML1 may not be disposed in the pad part PC. In addition, the first metal layer ML1 may not be disposed in a region other than a region overlapping the light-emitting element 10.

The solder pattern 162 may be disposed on the first electrode 161. The solder pattern 162 may be made of indium (In), tin (Sn), or an alloy thereof, but is not limited thereto. The solder pattern 162 may include a first portion 162a and a second portion 162b. The first portion 162a may contain indium (In) and the second portion 162b may contain gold (Au). The first portion 162a and the second portion 162b may be bonded by pressure when the light-emitting element 10 is transferred, and then may be eutectically bonded by applying heat thereto. When the second portion 162b is under pressure, a portion of the second portion 162b may cover at least a portion or all of the side surface of the first portion 162a. In this case, the contact area between the first portion 162a and the second portion 162b may be increased, thereby enhancing adhesion and improving the transmission of electrical signals.

The plurality of light-emitting elements 10 may each be mounted on the solder pattern 162.

A first-first optical layer 141a may cover the plurality of light-emitting elements 10 and the bank pattern 130. Thus, the first-first optical layer 141a may cover between the plurality of light-emitting elements 10 and between the plurality of bank patterns 130. The arrangement of the first-first optical layer 141a in plan view is the same as the arrangement of the first optical layer 141 in plan view.

The second electrode 170 may be disposed on the plurality of light-emitting elements 10. The second electrode 170 may be connected in common to the plurality of pixels PXL.

A first-second optical layer 141b may be disposed on the second electrode 170 to overlap the first-first optical layer 141a. By disposing the first-second optical layer 141b on the second electrode 170, the amount of light emitted in the forward direction may be increased.

The second optical layer 142 may be an organic insulating material surrounding the periphery of the first optical layer 141. The second optical layer 142 may be disposed on the insulating layer 122 together with the first optical layer 141. The first optical layer 142 may be disposed on the display area AA.

The black matrix 190 may be disposed on the first-second optical layer 141b, the second electrode 170, and the second optical layer 142. A transmission hole through which light from the light-emitting element 10 is emitted to the outside may be formed between the patterns of the black matrix 190.

The cover layer 180 may be an organic insulating material that covers the black matrix 190 and the second electrode 170.

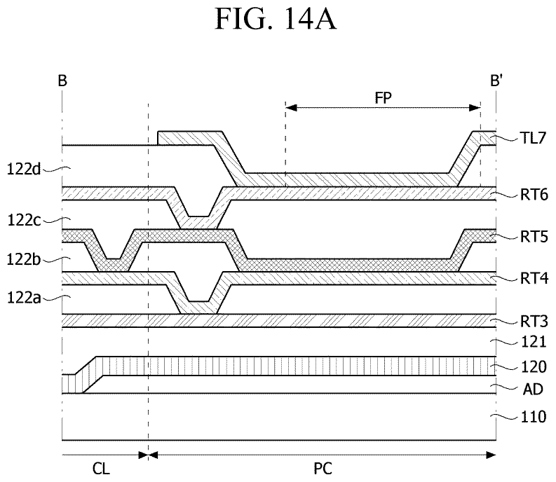

FIG. 12 is an enlarged plan view of area X of FIG. 10B.

Referring to FIG. 12, the planar shape of the third connection wire RT3 is shown in the connection wire area CL, and the upper portion of the seventh signal wire TL7 is shown in the pad part PC. In the connection wire area CL and the pad part PC, each of the connection wires RT3, RT4, RT5, and RT6, and the seventh signal wire TL7 may be disposed in the Y-axis direction.

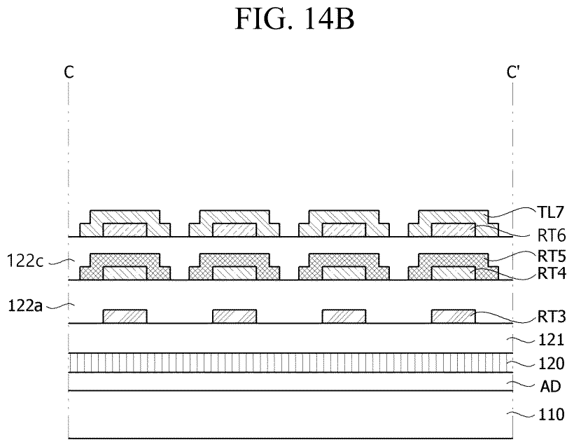

FIG. 13A is a cross-sectional view of a pad part according to a first embodiment of the present disclosure, taken along line B-B′ in FIG. 12. FIG. 13B is a cross-sectional view of a pad part according to the first embodiment of the present disclosure, taken along line C-C′ in FIG. 12.

In one embodiment of FIGS. 13A and 13B, as described with reference to FIG. 11, the connection wires RT3, RT4, RT5, and RT6 and the seventh signal wire TL7 may be separately disposed on the insulating layers 122a, 122b, 122c, and 122d in the connection wire area CL and the pad part PC, and may be electrically connected through at least one contact hole formed in each insulating layer in the connection wire area CL and/or the pad part PC.

That is, in the connection wire area CL and the pad part PC, the connection wires RT3, RT4, RT5, and RT6 and the seventh signal wire TL7 may not meet each other in a region other than a region in which the contact hole is formed. In FIGS. 13A and 13B, the third connection wire RT3, the fourth connection wire RT4, the fifth connection wire RT5, and the sixth connection wire RT6 are disposed in the first area FP, but this is merely an example, and other signal wires and/or connection wires, except for the seventh signal wire TL7, may not be disposed in the first area FP.

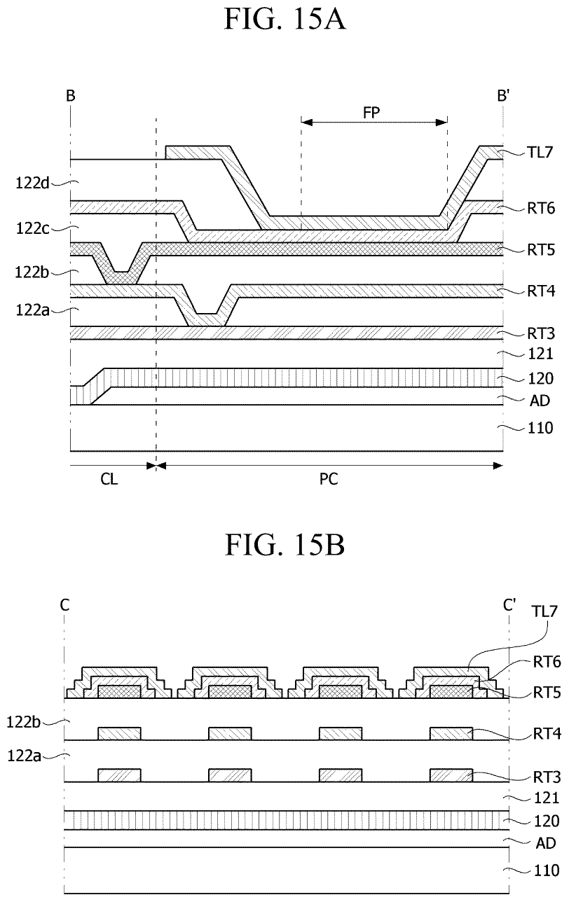

FIG. 14A is a cross-sectional view of a pad part according to a second embodiment of the present disclosure, taken along line B-B′ in FIG. 12. FIG. 14B is a cross-sectional view of a pad part according to the second embodiment of the present disclosure, taken along line C-C′ in FIG. 12.

Referring to FIGS. 14A and 14B, in the first area FP disposed within the pad part PC, the second insulating layer 122b and the fourth insulating layer 122d may be removed by patterning. On each of the fourth connection wires RT4 included in the first area FP, the fifth connection wire RT5 may be formed to further cover at least a portion including the top surface of the fourth connection wire RT4. The fourth connection wire RT4, the fifth connection wire RT5, the sixth connection wire RT6, and the seventh signal wire TL7 may be disposed in a first direction (the X-axis direction). The first area FP may have a length in the second direction (the Y-axis direction) along which each connection wire extends that is longer than a length in the first direction (the X-axis direction) perpendicular to the second direction.

On each of the sixth connection wires RT6 included in the first area FP, the seventh signal wire TL7 may be formed to further cover at least a portion including the top surface of the sixth connection wire RT6. The chip-on-film (COF) formed to at least partially overlap the first area FP may be bonded to the seventh signal wire TL7 by the anisotropic conductive film (ACF) disposed therebetween. In this case, the seventh signal wire TL7 and each insulating layer and/or each connection wire located therebelow may be broken or damaged due to a high load, resulting in increased signal resistance or poor reliability. When at least two wires are formed to be in direct contact with each other as in the present embodiment, the wires may withstand the load even when pressed by the anisotropic conductive film (ACF).

Referring to FIG. 14B, the fifth connection wire RT5 may be formed widely to cover the top and side surfaces of the fourth connection wire RT4. Thus, both ends of the fifth connection wire RT5 may be disposed on the first insulating layer 122a.

The seventh signal wire TL7 may be formed widely to cover the top and side surfaces of the sixth connection wire RT6. Thus, both ends of the seventh signal wire TL7 may be disposed on the third insulating layer 122c.

According to an embodiment, in the first area FP, the width of each of the fifth connection wire RT5 and the seventh signal wire TL7 may be greater than the width of each of the fourth connection wire RT4 and the sixth connection wire RT6. However, the present disclosure is not necessarily limited thereto, and the widths of the fourth connection wire RT4, the fifth connection wire RT5, the sixth connection wire RT6, and the seventh signal wire TL7 may be the same.

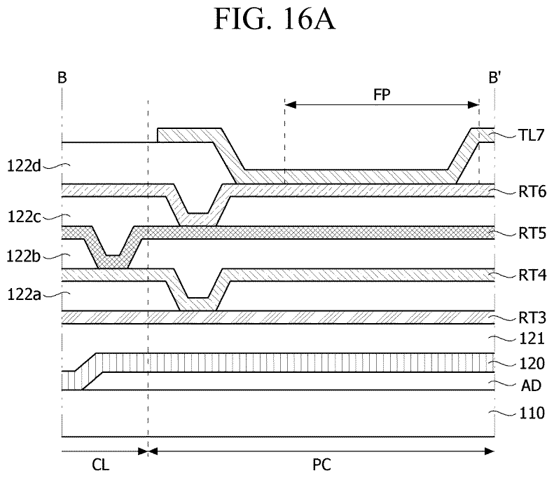

FIG. 15A is a cross-sectional view of a pad part according to a third embodiment of the present disclosure, taken along line B-B′ in FIG. 12. FIG. 15B is a cross-sectional view of a pad part according to the third embodiment of the present disclosure, taken along line C-C′ in FIG. 12.

Referring to FIGS. 15A and 15B, in the first area FP disposed within the pad part PC, the third insulating layer 122c and the fourth insulating layer 122d may be removed by patterning. On each of the fifth connection wires RT5 included in the first area FP, the sixth connection wire RT6 may be formed to further cover or contact at least a portion including the top surface of the fifth connection wire RT5. On each of the sixth connection wires RT6 included in the first area FP, the seventh signal wire TL7 may be formed to further cover or contact at least a portion including the top surface of the sixth connection wire RT6.

Referring to FIG. 15B, the sixth connection wire RT6 may be formed widely to cover the top and side surfaces of the fifth connection wire RT5. Thus, both ends of the sixth connection wire RT6 may be disposed on the second insulating layer 122b.

The seventh signal wire TL7 may be formed widely to cover the top and side surfaces of the sixth connection wire RT6. Thus, both ends of the seventh signal wire TL7 may be disposed on the second insulating layer 122b.

According to an embodiment, in the first area FP, the width of the seventh signal wire TL7 may be greater than the width of the sixth connection wire RT6. Further, the width of the sixth connection wire RT6 may be greater than the width of the fifth connection wire RT5. However, the present disclosure is not necessarily limited thereto, and the widths of the fourth connection wire RT4, the fifth connection wire RT5, the sixth connection wire RT6, and the seventh signal wire TL7 may be the same.

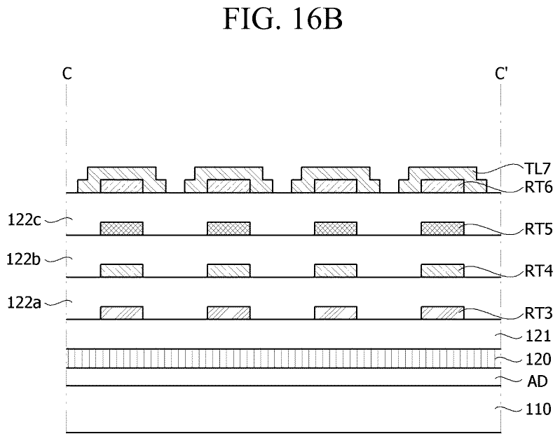

FIG. 16A is a cross-sectional view of a pad part according to a fourth embodiment of the present disclosure, taken along line B-B′ in FIG. 12. FIG. 16B is a cross-sectional view of a pad part according to the fourth embodiment of the present disclosure, taken along line C-C′ in FIG. 12.

Referring to FIGS. 16A and 16B, in the first area FP disposed within the pad part PC, the fourth insulating layer 122d may be removed by patterning. On each of the sixth connection wires RT6 included in the first area FP, the seventh signal wire TL7 may be formed to further cover or contact at least a portion including the top surface of the sixth connection wire RT6.

In FIGS. 16A and 16B, the third connection wire RT3, the fourth connection wire RT4, the fifth connection wire RT5, and the sixth connection wire RT6 are disposed in the first area FP, but this is merely an example, and other signal wires and/or connection wires, except for the seventh signal wire TL7, may not be disposed in the first area FP.

In an embodiment, a vertical structure has been described in which the driving electrodes 14 and 15 are disposed on the top and bottom of the light-emitting structure. However, the light-emitting element may have a lateral structure or a flip chip structure other than the vertical structure.

The display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation, an in-vehicle display device, a theater display device, a television, a wallpaper device, a signage device, a game device, a notebook, a monitor, a camera, a camcorder, a home appliance, and the like. In addition, the display device according to one or more embodiments of the present disclosure may be applied to an inorganic light-emitting lighting device.

The display device according to one or more embodiments of the present disclosure may be described as follows.

A display device according to one or more embodiments of the present disclosure may include: a substrate, a display area, a non-display area, a bending area, a connection wire area, a pad part, and a first area included in the pad part, wherein the first area may include: a first insulating layer disposed on the substrate; first connection wire disposed on the first insulating layer; a second connection wire disposed on the first connection wire; a second insulating layer disposed on the second connection wire; a third connection wire disposed on the second insulating layer; and a fourth connection wire disposed on the third connection wire.

The display area may include: the first insulating layer; a second-first connection wire and a third-first connection wire formed in the same process as the first connection wire; a third insulating layer disposed on the second-first connection wire and the third-first connection wire; a second-second connection wire and a third-second connection wire formed in the same process as the second connection wire and disposed on the third insulating layer; the second insulating layer disposed on the second-second connection wire and the third-second connection wire; a second-third connection wire and a third-third connection wire formed in the same process as the third connection wire and disposed on the second insulating layer; a fourth insulating layer disposed on the second-third connection wire and the third-third connection wire; and a signal wire formed in the same process as the fourth connection wire and disposed on the fourth insulating layer.

The first connection wire, the second connection wire, the third connection wire, and the fourth connection wire may be formed of a plurality of metal layers, wherein the fourth connection wire may include one more metal layer than each of the first connection wire, the second connection wire, and the third connection wire.

The fourth insulating layer may not be disposed in the bending area.

Within the pad part, portions of the first connection wire, the second connection wire, the third connection wire, and the fourth connection wire may extend out of the first area; the first insulating layer, the third insulating layer, the second insulating layer, and the fourth insulating layer may be disposed in an area other than the first area within the pad part, and the first connection wire, the second connection wire, the third connection wire, and the fourth connection wire may be electrically connected through at least one contact hole formed in each of the first insulating layer, the second insulating layer, the third insulating layer, and the fourth insulating layer.

The first connection wire, the second connection wire, the third connection wire, and the fourth connection wire may be disposed in a first direction, and the first area may have a length in the first direction that is shorter than a length in a second direction perpendicular to the first direction.

The second connection wire may cover top and side surfaces of the first connection wire, and the fourth connection wire may cover top and side surfaces of the third connection wire.

In addition, the display device may further include: an adhesive layer disposed between the substrate and the first insulating layer; a pixel driving circuit disposed on the adhesive layer; a protective layer disposed on the pixel driving circuit; and a second-fourth connection wire and a third-fourth connection wire disposed in the display area, and a fifth connection wire disposed in the first area, between the protective layer and the first insulating layer.

In addition, the display device may further include: a bank pattern disposed on the fourth insulating layer; a first electrode disposed on the bank pattern; a first metal layer disposed on the first electrode; a solder pattern disposed on the first metal layer; a light-emitting element disposed on the solder pattern; and a second electrode disposed on the light-emitting element.

The fifth connection wire may extend from the pad part to the display area, and only the fifth connection wire and n (where 0<n<5 and n is an integer) insulating layers may be disposed in the bending area.

A display device according to one or more embodiments of the present disclosure may include: a substrate, a display area, a non-display area, a bending area, a connection wire area, a pad part, and a first area included in the pad part, wherein the first area may include: a first insulating layer disposed on the substrate; a first connection wire disposed on the first insulating layer; a second insulating layer disposed on the first connection wire; a second connection wire disposed on the second insulating layer; a third connection wire disposed on the second connection wire; and a fourth connection wire disposed on the third connection wire.

The display area may include: the first insulating layer; a second-first connection wire and a third-first connection wire formed in the same process as the first connection wire; the second insulating layer disposed on the second-first connection wire and the third-first connection wire; a second-second connection wire and a third-second connection wire formed in the same process as the second connection wire and disposed on the second insulating layer; a third insulating layer disposed on the second-second connection wire and the third-second connection wire; a second-third connection wire and a third-third connection wire formed in the same process as the third connection wire and disposed on the third insulating layer; a fourth insulating layer disposed on the second-third connection wire and the third-third connection wire; and a signal wire formed in the same process as the fourth connection wire and disposed on the fourth insulating layer.

The first connection wire, the second connection wire, the third connection wire, and the fourth connection wire may be formed of a plurality of metal layers, wherein the fourth connection wire may include one more metal layer than the first connection wire, the second connection wire, and the third connection wire.

The fourth insulating layer may not be disposed in the bending area.

Within the pad part, portions of the first connection wire, the second connection wire, the third connection wire, and the fourth connection wire may extend out of the first area, the first insulating layer, the third insulating layer, the second insulating layer, and the fourth insulating layer may be disposed in an area other than the first area within the pad part; and the first connection wire, the second connection wire, the third connection wire, and the fourth connection wire may be electrically connected through at least one contact hole formed in each of the first insulating layer, the second insulating layer, the third insulating layer, and the fourth insulating layer.

The first connection wire, the second connection wire, the third connection wire, and the fourth connection wire may be disposed in a first direction, and the first area may have a length in the first direction that is shorter than a length in a second direction perpendicular to the first direction.

The second connection wire may cover top and side surfaces of the first connection wire, and the fourth connection wire may cover top and side surfaces of the third connection wire.

The display device may further include: an adhesive layer disposed between the substrate and the first insulating layer; a pixel driving circuit disposed on the adhesive layer; a protective layer disposed on the pixel driving circuit; and a second-fourth connection wire and a third-fourth connection wire disposed in the display area, and a fifth connection wire disposed in the first area, between the protective layer and the first insulating layer.

In addition, the display device may further include: a bank pattern disposed on the fourth insulating layer; a first electrode disposed on the bank pattern; a first metal layer disposed on the first electrode; a solder pattern disposed on the first metal layer; a light-emitting element disposed on the solder pattern; and a second electrode disposed on the light-emitting element.

In addition, the fifth connection wire may extend from the pad part to the display area, and only the fifth connection wire and n (where 0<n<5 and n is an integer) insulating layers are disposed in the bending area.

The descriptions of the problem to be solved, the means to solve the problem, and the effect described above does not specify the essential features of the claims, and therefore the scope of the claims is not limited by details described in the specification.

Although the embodiments of the present disclosure have been described in more detail with reference to the accompanying drawings, the present disclosure is not necessarily limited to such embodiments, and may be variously modified within the scope thereof without departing from the technical spirit of the present disclosure. Therefore, the embodiments disclosed in the present disclosure are provided for illustrative purposes only and are not intended to limit the technical concept of the present disclosure, and the scope of the technical concept of the present disclosure is not limited thereto. Therefore, it should be understood that the embodiments described above are illustrative in all aspects and do not limit the present disclosure. The scope of protection of the present disclosure should be construed on the basis of the following claims, and all technical concepts within the equivalent scope thereof should be construed as falling within the scope of the present disclosure.

What is claimed is:

1. A display device, comprising:
a substrate, a display area, a non-display area, a bending area, a connection wire area, a pad part, and a first area included in the pad part,
wherein the first area includes:
a first insulating layer disposed on the substrate;
a first connection wire disposed on the first insulating layer;
a second connection wire disposed on the first connection wire;
a second insulating layer disposed on the second connection wire;
a third connection wire disposed on the second insulating layer; and
a fourth connection wire disposed on the third connection wire.

2. The display device of claim 1, wherein the display area includes:
the first insulating layer;
a second-first connection wire and a third-first connection wire formed in a same process as the first connection wire;
a third insulating layer disposed on the second-first connection wire and the third-first connection wire;
a second-second connection wire and a third-second connection wire formed in a same process as the second connection wire and disposed on the third insulating layer;
the second insulating layer disposed on the second-second connection wire and the third-second connection wire;
a second-third connection wire and a third-third connection wire formed in a same process as the third connection wire and disposed on the second insulating layer;
a fourth insulating layer disposed on the second-third connection wire and the third-third connection wire; and
a signal wire formed in a same process as the fourth connection wire and disposed on the fourth insulating layer.

3. The display device of claim 1, wherein the first connection wire, the second connection wire, the third connection wire, and the fourth connection wire are formed of a plurality of metal layers, and
wherein the fourth connection wire includes one more metal layer than each of the first connection wire, the second connection wire, and the third connection wire.

4. The display device of claim 2, wherein the fourth insulating layer is not disposed in the bending area.

5. The display device of claim 2, wherein:
within the pad part, portions of the first connection wire, the second connection wire, the third connection wire, and the fourth connection wire extend out of the first area,
the first insulating layer, the third insulating layer, the second insulating layer, and the fourth insulating layer are disposed in an area other than the first area within the pad part, and
the first connection wire, the second connection wire, the third connection wire, and the fourth connection wire are for being electrically connected through at least one contact hole formed in each of the first insulating layer, the second insulating layer, the third insulating layer, and the fourth insulating layer.

6. The display device of claim 2, wherein the first connection wire, the second connection wire, the third connection wire, and the fourth connection wire are disposed in a first direction, and the first area has a length in the first direction that is shorter than a length in a second direction perpendicular to the first direction.

7. The display device of claim 2, wherein the second connection wire covers top and side surfaces of the first connection wire, and the fourth connection wire covers top and side surfaces of the third connection wire.

8. The display device of claim 2, further comprising:
an adhesive layer disposed between the substrate and the first insulating layer;
a pixel driving circuit disposed on the adhesive layer;
a protective layer disposed on the pixel driving circuit; and
a second-fourth connection wire and a third-fourth connection wire disposed in the display area, and a fifth connection wire disposed in the first area, between the protective layer and the first insulating layer.

9. The display device of claim 7, further comprising:
a bank pattern disposed on the fourth insulating layer;
a first electrode disposed on the bank pattern;
a first metal layer disposed on the first electrode;
a solder pattern disposed on the first metal layer;
a light-emitting element disposed on the solder pattern; and
a second electrode disposed on the light-emitting element.

10. The display device of claim 8, wherein the fifth connection wire extends from the pad part to the display area, and only the fifth connection wire and n (where 0<n<5 and n is an integer) insulating layers are disposed in the bending area.

11. The display device of claim 9, wherein the first electrode includes:
a second metal layer disposed below the first metal layer;
a third metal layer disposed below the second metal layer; and
a fourth metal layer disposed below the third metal layer,
wherein the second metal layer is formed of a material having a different resistance value than each of the first metal layer and the third metal layer, and the fourth metal layer is formed of a same material as the second metal layer.

12. The display device of claim 11, wherein the first metal layer is disposed to be in contact with a lower portion of the solder pattern and is for being electrically connected to the solder pattern.

13. The display device of claim 11, wherein the second metal layer is formed of a material that has a lower light reflectivity but a higher resistance value than the third metal layer, and the third metal layer is formed of a material having a higher light reflectivity than the first metal layer.

14. The display device of claim 11, wherein the first metal layer is disposed only in a region overlapping the first electrode and the light-emitting element, and the first metal layer is not disposed in the pad part.

15. The display device of claim 9, wherein the solder pattern includes a first portion and a second portion, and
wherein the first portion contains indium and the second portion contains gold, and when the second portion is under pressure, a portion of the second portion covers at least a portion or all of a side surface of the first portion.

16. The display device of claim 1, wherein in the first area, a width of each of the second connection wire and the fourth connection wire is greater than or equal to a width of each of the first connection wire and the third connection wire.

17. The display device of claim 2, wherein the fourth insulating layer is not disposed in the bending area, and the non-display area and the connection wire area are adjacent to the bending area.

18. The display device of claim 1, wherein the fourth connection wire is disposed to contact at least a portion of a top surface of the third connection wire.

19. The display device of claim 18, wherein the third connection wire is disposed to contact at least a portion of a top surface of the second connection wire.

20. A display device, comprising:
a substrate including a display area, a non-display area, a bending area, a connection wire area, a pad part, and a first area included in the pad part,
wherein the first area includes:
a first insulating layer disposed on the substrate;
a first connection wire disposed on the first insulating layer;
a second insulating layer disposed on the first connection wire;
a second connection wire disposed on the second insulating layer;
a third connection wire disposed on the second connection wire; and
a fourth connection wire disposed on the third connection wire.
